(19) United States
(12) Patent Application Publication
(10) Pub. No.: US 2026/0090143 A1
(43) Pub. Date: Mar. 26, 2026

(54) PIXEL STRUCTURE

(71) Applicant: AUO Corporation, Hsinchu City (TW)

(72) Inventors: Yu-Hsin Huang, Hsinchu City (TW); Chia-An Lee, Hsinchu City (TW); Yi-Hong Chen, Hsinchu City (TW); YinYu Chen, Hsinchu City (TW); Wen-Wei Yang, Hsinchu City (TW); Kuan-Heng Lin, Hsinchu City (TW)

(73) Assignee: AUO Corporation, Hsinchu City (TW)

(21) Appl. No.: 18/939,567

(22) Filed: Nov. 7, 2024

(30) Foreign Application Priority Data
Sep. 25, 2024 (TW) 113136394

(51) Int. Cl. H01L 33/20; H01L 33/38

(52) U.S. Cl. CPC H10H 20/819; H10H 20/8312

(57) ABSTRACT

A light-emitting element includes a first type semiconductor layer, a second type semiconductor layer, an active layer, an intrinsic semiconductor layer, a first electrode and a second electrode. The second type semiconductor layer is disposed opposite to the first type semiconductor layer. The active layer is disposed between the first type semiconductor layer and the second type semiconductor layer. The intrinsic semiconductor layer has multiple microstructures. The second type semiconductor layer is disposed between the intrinsic semiconductor layer and the active layer. The first electrode and the second electrode are respectively disposed on opposite sides of the active layer. The second electrode is disposed in a through hole of the intrinsic semiconductor layer and a recess of the second type semiconductor layer.

### CROSS-REFERENCE TO RELATED APPLICATION

This application claims the priority benefit of Taiwan application serial no. 113136394, filed on Sep. 25, 2024. The entirety of the above-mentioned patent application is hereby incorporated by reference herein and made a part of this specification.

### BACKGROUND

### Technical Field

The disclosure relates to a semiconductor element, and in particular to a light-emitting element.

### Description of Related Art

A light-emitting diode display panel includes an active component substrate and a plurality of light-emitting diode devices transferred onto the active component substrate.

Inheriting the characteristics of light-emitting diodes, the light-emitting diode display panel has advantages of power saving, high efficiency, high brightness, and fast response time. In addition, compared with an organic light-emitting diode display panel, the light-emitting diode display panel further has advantages of easy color adjustment, long light emission life, no image burn-in, etc. Therefore, the light-emitting diode display panel is considered as a display technology of the next generation. The light-emitting diode devices include a vertical light-emitting diode device. Generally speaking, an upper electrode of the vertical light-emitting diode device is made of non-translucent metal and is disposed in a center of the vertical light-emitting diode device, which is not conducive to emit light in a normal direction.

### SUMMARY

This disclosure provides a light-emitting element with good performance.

A light-emitting element of an embodiment of this disclosure includes a first type semiconductor layer, a second type semiconductor layer, an active layer, an intrinsic semiconductor layer, a first electrode and a second electrode. The second type semiconductor layer is disposed opposite to the first type semiconductor layer. The active layer is disposed between the first type semiconductor layer and the second type semiconductor layer. The intrinsic semiconductor layer has microstructures. The second type semiconductor layer is disposed between the intrinsic semiconductor layer and the active layer. The first electrode and the second electrode are respectively disposed on opposite sides of the active layer and electrically connected to the first type semiconductor layer and the second type semiconductor layer respectively. The intrinsic semiconductor layer has a through hole. The second type semiconductor layer has a recess. The through hole of the intrinsic semiconductor layer is connected with the recess of the second type semiconductor layer. The second electrode is disposed in the through hole of the intrinsic semiconductor layer and the recess of the second type semiconductor layer.

### BRIEF DESCRIPTION OF THE DRAWINGS

FIG. 1 is a schematic cross-sectional view of a light-emitting element according to an embodiment of this disclosure.

FIG. 2 is a schematic top view of a light-emitting element according to an embodiment of this disclosure.

FIG. 3 is a schematic cross-sectional view of a light-emitting element of a comparative example.

FIG. 4 shows light intensity distributions at tilt angles of the light-emitting element of the comparative example in FIG. 3 and the light-emitting element of the embodiment in FIG. 1 in an orientation parallel to the first direction d1 or parallel to the second direction d2.

FIG. 5 is a schematic cross-sectional view of a light-emitting element according to another embodiment of the present disclosure.

FIG. 6 is a schematic cross-sectional view of a light-emitting element of another comparative example.

FIG. 7 is a schematic top view of a light-emitting element according to another embodiment of the present disclosure.

FIG. 8 is a schematic cross-sectional view of the light-emitting element of another embodiment of the disclosure.

FIG. 9 is a schematic cross-sectional view of the light-emitting element of another embodiment of the disclosure.

FIG. 10 shows the light intensity distribution of the light-emitting element 100B of the embodiment of FIGS. 7 to 9 in an orientation parallel to the first direction d1 and in an orientation parallel to the second direction d2 at each of tilt angles.

FIG. 11 is a schematic top view of a light-emitting element according to yet another embodiment of the present disclosure.

FIG. 12 is a schematic cross-sectional view of a light-emitting element according to yet another embodiment of the disclosure.

FIG. 13 is a schematic cross-sectional view of a light-emitting element according to yet another embodiment of the present disclosure.

FIG. 14 is a top or bottom view of a light-emitting element according to an embodiment of this disclosure.

FIG. 15 is a top or bottom view of the light-emitting element of another embodiment of the present disclosure.

FIG. 16 is a top or bottom view of the light-emitting element of another embodiment of the disclosure.

FIG. 17 is a schematic top or bottom view of the light-emitting element of yet another embodiment of the disclosure.

FIG. 18 is a top or bottom view of a light-emitting element according to an embodiment of the present disclosure.

FIG. 19 is a top or bottom view of the light-emitting element of another embodiment of the present disclosure.

FIG. 20 is a top or bottom view of the light-emitting element of another embodiment of the disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, +30%, +20%, +10%, or +5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

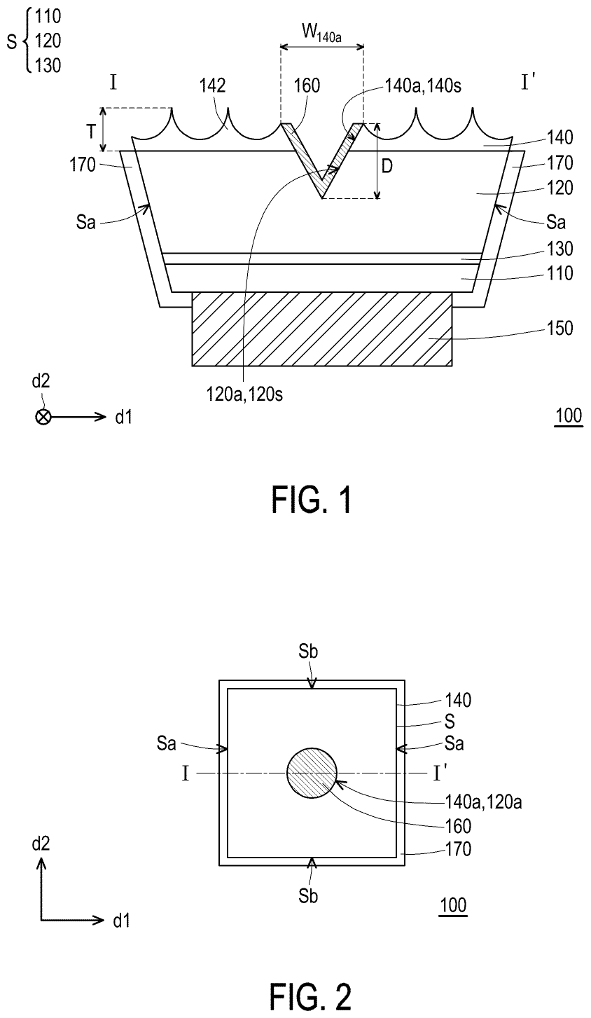

FIG. 1 is a schematic cross-sectional view of a light-emitting element according to an embodiment of this disclosure. FIG. 2 is a schematic top view of a light-emitting element according to an embodiment of this disclosure. FIG. 1 corresponds to the line segment I-I′ in FIG. 2.

Referring to FIGS. 1 and 2, the light-emitting element 100 includes a first type semiconductor layer 110, a second type semiconductor layer 120, an active layer 130, an intrinsic semiconductor layer 140, a first electrode 150 and a second electrode 160. The second type semiconductor layer 120 is disposed opposite the first type semiconductor layer 110. The active layer 130 is disposed between the first type semiconductor layer 110 and the second type semiconductor layer 120. The intrinsic semiconductor layer 140 has microstructures 142. The microstructures 142 are used to increase light extraction efficiency. The second type semiconductor layer 120 is disposed between the intrinsic semiconductor layer 140 and the active layer 130. In some embodiments, the first type semiconductor layer 110 may be a p-type semiconductor layer, the second type semiconductor layer 120 may be an n-type semiconductor layer, and the active layer 130 may be a multiple quantum well structure. For example, in some embodiments, the first type semiconductor layer 110 may be p-type gallium nitride, and the second type semiconductor layer 120 may be n-type gallium nitride, but this disclosure is not limited thereto. In some embodiments, the intrinsic semiconductor layer 140 is in contact with the second type semiconductor layer 120. The intrinsic semiconductor layer 140 is an undoped semiconductor layer. For example, in some embodiments, the intrinsic semiconductor layer 140 may be undoped gallium nitride, but this disclosure is not limited to thereto.

The first electrode 150 and the second electrode 160 are respectively disposed on opposite sides of the active layer 130 and are electrically connected to the first type semiconductor layer 110 and the second type semiconductor layer 120 respectively. The first type semiconductor layer 110 is disposed between the active layer 130 and the first electrode 150. The second type semiconductor layer 120 is disposed between the second electrode 160 and the active layer 130. The intrinsic semiconductor layer 140 is disposed between the second electrode 160 and the second type semiconductor layer 120. In some embodiments, the first electrode 150 contacts first type semiconductor layer 110. In some embodiments, the second electrode 160 contacts the intrinsic semiconductor layer 140 and the second type semiconductor layer 120. In some embodiments, a material of the first electrode 150 may include metal (eg, gold), and a material of the second electrode 160 may include metal (eg, aluminum), but this disclosure is not limited thereto.

The semiconductor structure S includes the first type semiconductor layer 110, the second type semiconductor layer 120 and the active layer 130. A first direction d1 and a second direction d2 are staggered and substantially parallel to the active layer 130. The semiconductor structure S has first side walls Sa arranged in the first direction d1 and second side walls Sb arranged in the second direction d2. In some embodiments, the light-emitting element 100 further includes an insulation layer 170 disposed on the first side walls Sa and the second side walls Sb of the semiconductor structure S. In some embodiments, a material of the insulation layer 170 is, for example, silicon oxide, but this disclosure is not limited thereto.

It is worth noting that the intrinsic semiconductor layer 140 has a through hole 140a, the second type semiconductor layer 120 has a recess 120a, the through hole 140a of the intrinsic semiconductor layer 140 is connected to the recess 120a of the second type semiconductor layer 120, and at least one portion of the second electrode 160 is disposed on the through hole 140a of the intrinsic semiconductor layer and the recess 120a of the second type semiconductor layer 120. In some embodiments, the through hole 140a of the intrinsic semiconductor layer 140 and the recess 120a of the second type semiconductor layer 120 may form a conical recess. In some embodiments, the second electrode 160 is disposed in the conical recess and may be conical. In some embodiments, during a manufacturing process of the light-emitting element 100, the through hole 140a of the intrinsic semiconductor layer 140 and the recess 120a of the second type semiconductor layer 120 are formed in the same etching process. Therefore, the side wall 140s of the intrinsic semiconductor layer 140 defining the through hole 140a and the side wall 120s defining the recess 120a of the second type semiconductor layer 120 may be substantially aligned. That is to say, in a top view of the light-emitting element 100, the through hole 140a of the intrinsic semiconductor layer 140 and the recess 120a of the second type semiconductor layer 120 are substantially coincided.

In some embodiments, the intrinsic semiconductor layer 140 has a thickness T, and a sum D of a depth of the recess 120a and a depth of the through hole 140a may fall within a range of “thickness T of the intrinsic semiconductor layer 140+0.2 μm” to “thickness T of the intrinsic semiconductor layer 140+1.5 μm”. In some embodiments, for example, the thickness T of the intrinsic semiconductor layer 140 falls in a range of 2 μm˜6 μm, but this disclosure is not limited to thereto. In some embodiments, the width W₁₄₀ₐ of the through hole 140a of the intrinsic semiconductor layer 140 may fall in a range of 0.1 μm˜4 μm, but this disclosure is not limited to thereto.

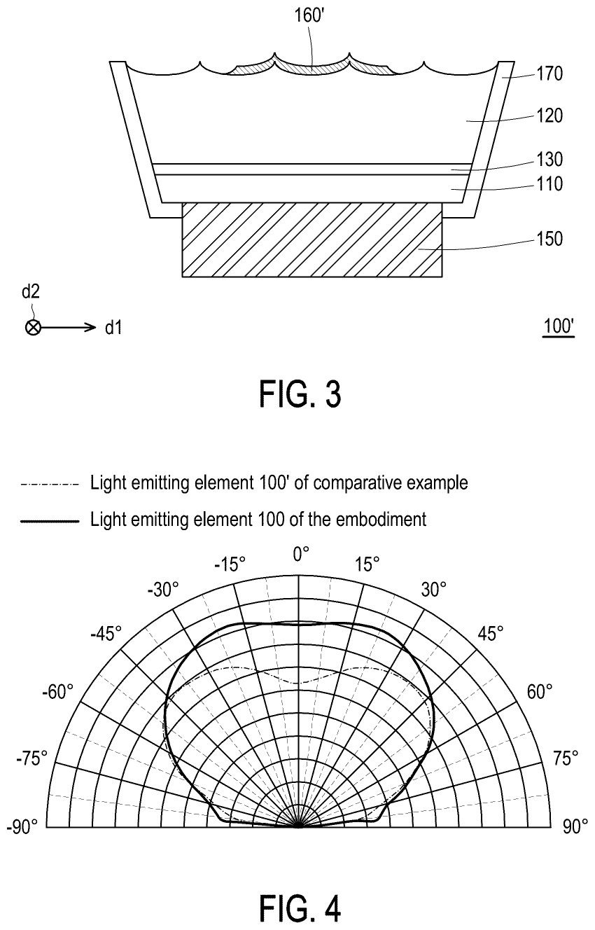

It is worth mentioning that the through hole 140a of the intrinsic semiconductor layer 140 and the recess 120a of the second type semiconductor layer 120 form a conical recess. The second electrode 160 is formed in the conical recess, so that local ohmic contact can be realized without excessively damaging the microstructures 142. At the same time, the second electrode 160 disposed in the conicalrecess also has a mechanism for recovering light beams, and has less impact on blocking the emission of light beams. In addition, the vertical projection area of the contact range between the second electrode 160 disposed in the conicalrecess and the second type semiconductor layer 120 is smaller, so that the second electrode 160 has a better effect in limiting current to avoid side wall non-radiative recombination. In this way, the light extraction efficiency and light intensity in a normal direction of the light-emitting element 100 can be significantly improved. The following is an example with reference to FIG. 3, FIG. 4 and Table 1.

FIG. 3 is a schematic cross-sectional view of a light-emitting element of a comparative example. The light-emitting element 100′ of the comparative example in FIG. 3 is similar to the light-emitting element 100 of the embodiment of FIG. 1. The difference between the two is that the light-emitting element 100′ of the comparative example in FIG. 3 does not include multiple microstructures 142 of the intrinsic semiconductor layer 140 in FIG. 1; the second electrode 160′ of the comparative example in FIG. 3 is formed on the surface of the second type semiconductor layer 120 rather than in the through hole 140a of the intrinsic semiconductor layer 140 and the recess 120a of the second type semiconductor layer 120 in FIG. 1.

Referring to FIGS. 1 and 3, FIG. 4 shows light intensity distributions at tilt angles of the light-emitting element 100′ of the comparative example in FIG. 3 and the light-emitting element 100 of the embodiment in FIG. 1 in an orientation parallel to the first direction d1 or parallel to the second direction d2. Table 1 lists the light extraction efficiency and relative light intensity in a normal direction of the light-emitting element 100′ of the comparative example in FIG. 3 and the light-emitting element 100 of the embodiment in FIG. 1.

TABLE 1

| | light | relative light |
|---|---|---|
| | extraction | intensity in a |
| | efficiency | normal direction |
| Light-emitting element 100′ of the | 40.3% | 100.0% |
| comparative example in FIG. 3 | | |
| Light-emitting element 100 of the | 43.0% | 140.5% |
| embodiment in FIG. 1 | | |

Referring to FIG. 1, FIG. 3, FIG. 4 and Table 1, according to the data in FIG. 4 and Table 1, it can be known that compared with the light-emitting element 100′ of the comparative example, the light extraction efficiency and light intensity of the light-emitting element 100 of the embodiment in a normal direction are significantly improved.

In the following embodiment, the reference numerals and part of the description of the foregoing embodiment are applied, where the same reference numerals are used to indicate the same or similar components, and descriptions of the same technical contents are omitted. Reference may be made to the foregoing embodiment for the omitted descriptions, which will not be repeated in following embodiment.

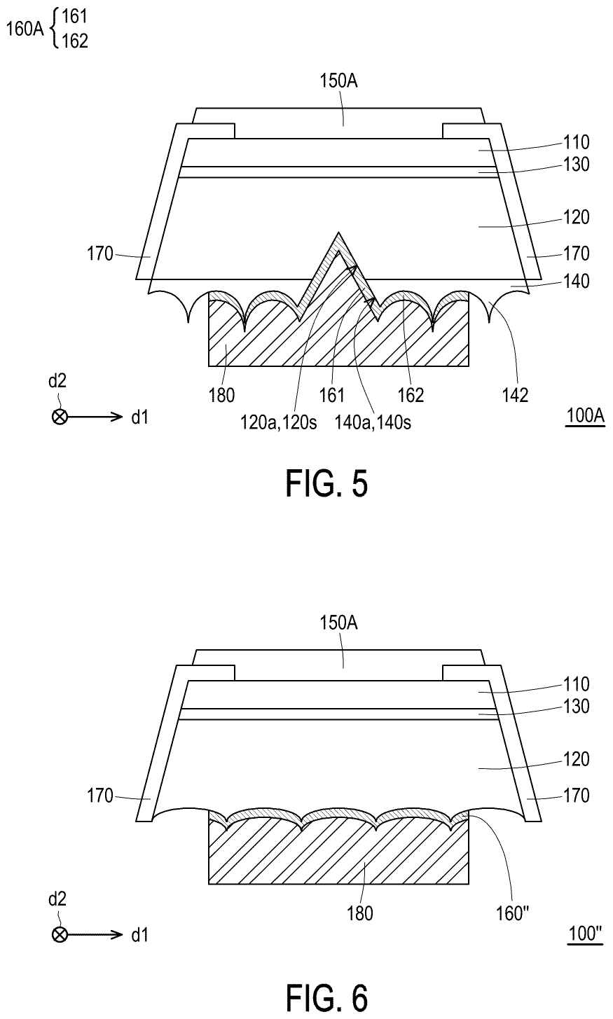

FIG. 5 is a schematic cross-sectional view of a light-emitting element according to another embodiment of the present disclosure. The light-emitting element 100A in FIG. 5 is similar to the light-emitting element 100 in FIG. 1. The main difference between the two is that in the embodiment of FIG. 1, the second type semiconductor layer 120 is on the top and the first type semiconductor layer 110 is on the bottom; in the embodiment of FIG. 5, the first type semiconductor layer 110 is on top and the second type semiconductor layer 120 is on the bottom.

In addition, in the embodiment of FIG. 5, the second electrode 160A has a first portion 161 and a second portion 162 connected to the first portion 161. The first portion 161 of the second electrode 160A is disposed in the through hole 140a of the intrinsic semiconductor layer 140 and the recess 120a of the second type semiconductor layer 120. The second portion 162 is located outside the through hole 140a of the intrinsic semiconductor layer 140 and the recess 120a of the second type semiconductor layer 120 and is disposed on the microstructures 142 of the intrinsic semiconductor layer 140, and the first electrode 150A is translucent. For example, in some embodiments, a material of the first electrode 150A may be indium tin oxide, indium zinc oxide, aluminum tin oxide, aluminum zinc oxide, indium germanium zinc oxide, other suitable oxides, or stacked layers of at least two of the above, but this disclosure is not limited to thereto.

Furthermore, in the embodiment of FIG. 5, the light-emitting element 100A may optionally include a third electrode 180 disposed on the second electrode 160A. The third electrode 180 is directly connected to the second electrode 160A, and the combination of the third electrode 180 and the second electrode 160A can be regarded as a lower electrode of the light-emitting element 100A. In some embodiments, a material of the third electrode 180 is, for example, gold, but this disclosure is not limited to thereto.

FIG. 6 is a schematic cross-sectional view of a light-emitting element of another comparative example. The light-emitting element 100″ of the comparative example in FIG. 6 is similar to the light-emitting element 100A of the embodiment in FIG. 5. The difference between the two is that the light-emitting element 100″ of the comparative example in FIG. 6 does not include the intrinsic semiconductor layer 140 with multiple microstructures 142 in FIG. 5; the second electrode 160″ of the comparative example in FIG. 6 is formed on the surface of the second type semiconductor layer 120 instead of in the through hole 140a of the intrinsic semiconductor layer 140 and the recess 120a of the second type semiconductor layer 120 in FIG. 5.

Table 2 lists the light extraction efficiency and relative light intensity in a normal direction of the light-emitting element 100″ of the comparative example in FIG. 6 and the light-emitting element 100A of the embodiment in FIG. 5.

TABLE 2

| | light | relative light |
|---|---|---|
| | extraction | intensity in a |
| | efficiency | normal direction |
| light-emitting element 100″ of the | 43.0% | 100.0% |
| comparative example in FIG. 6 | | |
| light-emitting element 100A of | 45.0% | 103.3% |
| the embodiment in FIG. 5 | | |

Referring to FIG. 5, FIG. 6 and Table 2, according to the data in Table 2, it can be known that compared with the light-emitting element 100″ of the comparative example, the light extraction efficiency and light intensity in a normal direction of the light-emitting element 100A of the embodiment are both slightly improved.

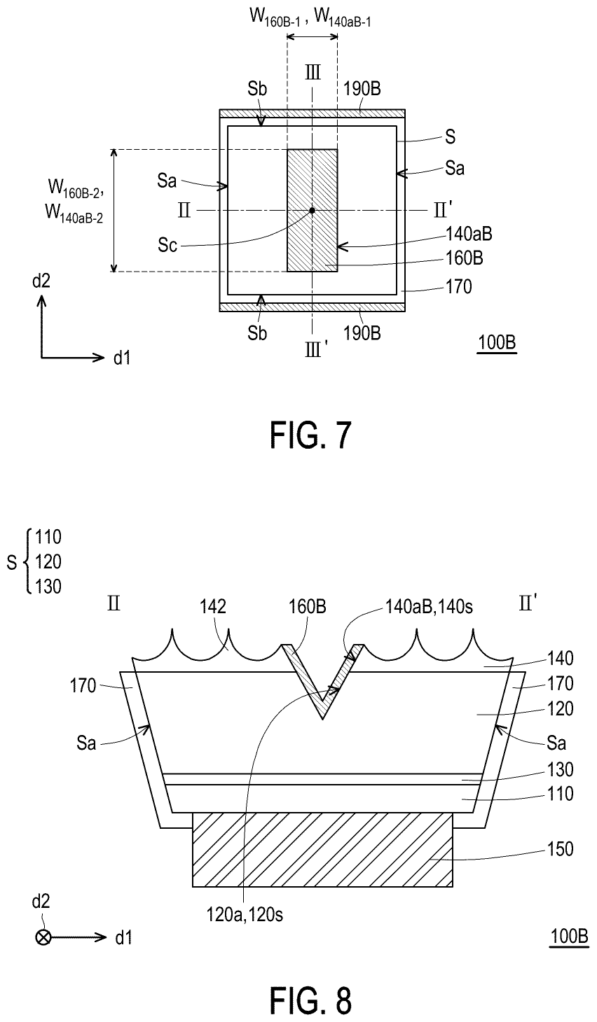

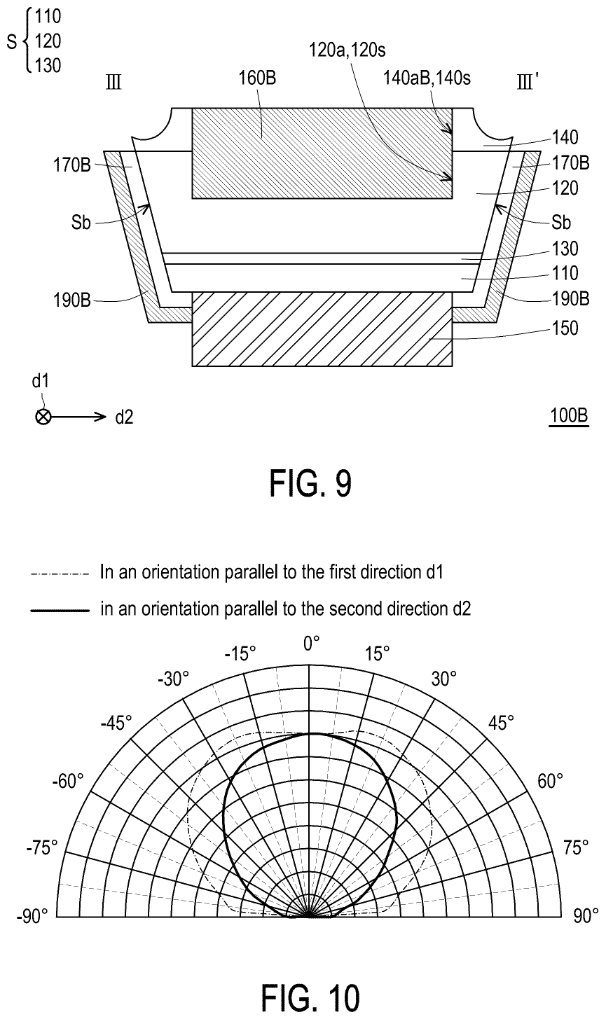

FIG. 7 is a schematic top view of a light-emitting element according to another embodiment of the present disclosure. FIG. 8 is a schematic cross-sectional view of the light-emitting element of another embodiment of the disclosure. FIG. 9 is a schematic cross-sectional view of the light-emitting element of another embodiment of the disclosure. FIG. 8 corresponds to the line segment II-II′ of FIG. 7. FIG. 9 corresponds to the line segment III-III′ of FIG. 7.

The light-emitting element 100B in FIGS. 7 to 9 is similar to the light-emitting element 100 in FIGS. 1 to 2. The main difference between the two is that the second electrode 160B of the light-emitting element 100B in FIGS. 7 to 9 is different from the second electrode 160 of the light-emitting element 100B in FIGS. 1 to 2.

Referring to FIGS. 7, 8 and 9, specifically, in this embodiment, the second electrode 160B has first length W_{160B-1} and second length W_{160B-2} in the first direction d1 and the second direction d2 respectively, and the first length W_{160B-1} is smaller than second length W_{160B-2}. In this embodiment, the through hole 140aB of the intrinsic semiconductor layer 140 has a first length W_{140aB-1} and a second length W_{140aB-2} in the first direction d1 and the second direction d2 respectively, and the first length W_{140aB-1} is smaller than the second length W_{140aB-2}.

In addition, in this embodiment, the light-emitting element 100B further includes a reflective structure 190B, which is disposed on the second side walls Sb of the semiconductor structure S and is not disposed on the first side walls Sb of the semiconductor structure S. However, this disclosure is not limited to thereto. In other embodiments not shown, the reflective structure 190B may be disposed on the entire side wall of the semiconductor structure S. In this embodiment, the reflective structure 190B is, for example, a single-layer structure, and a material of the reflective structure 190B is, for example, metal. However, this disclosure is not limited to thereto. In other embodiments not shown, the reflective structure 190B may be a distributed Bragg reflector (DBR) including a multi-layer structure.

FIG. 10 shows the light intensity distribution of the light-emitting element 100B of the embodiment of FIGS. 7 to 9 in an orientation parallel to the first direction d1 and in an orientation parallel to the second direction d2 at each of tilt angles. Referring to FIGS. 7 to 10, in this embodiment, the light field shape of the light-emitting element 100B in the direction parallel to the second direction d2 (that is, in the up and down viewing angle direction) can be narrowed through the elongated second electrode 160B. Referring to FIG. 7, in this embodiment, the second electrode 160B and the through hole 140aB may be selectively located on the geometric center Sc of the semiconductor structure S, and the light field shape of the light-emitting element 100B in the direction parallel to the first direction d1 (that is, in the left and right viewing angle directions) may be symmetrical, but this disclosure is not limited to thereto.

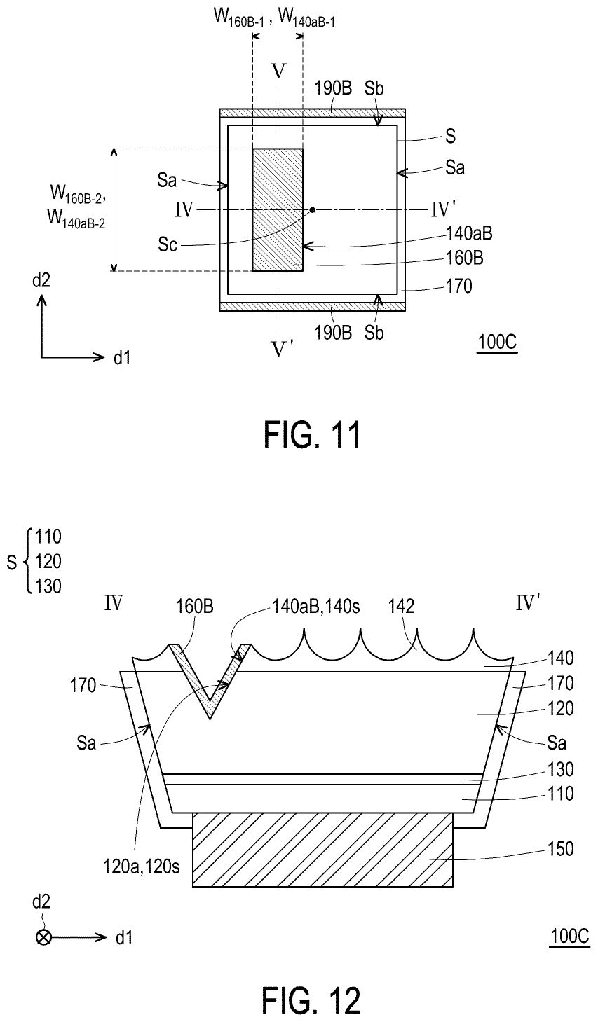

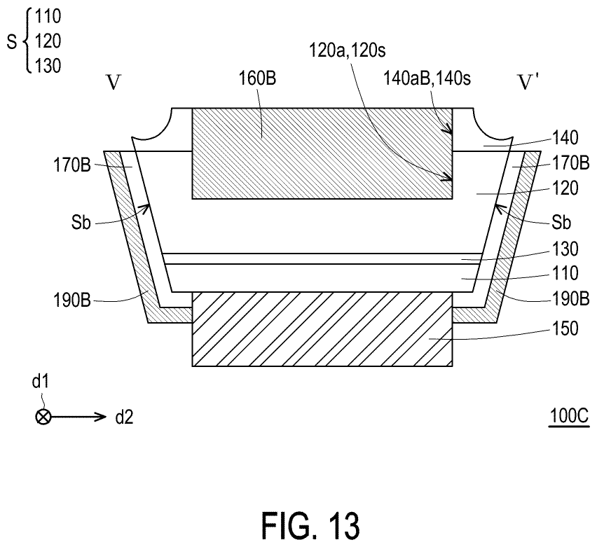

FIG. 11 is a schematic top view of a light-emitting element according to yet another embodiment of the present disclosure. FIG. 12 is a schematic cross-sectional view of a light-emitting element according to yet another embodiment of the disclosure. FIG. 13 is a schematic cross-sectional view of a light-emitting element according to yet another embodiment of the present disclosure. FIG. 12 corresponds to the line segment IV-IV′ of FIG. 11. FIG. 13 corresponds to the line segment V-V′ in FIG. 11.

The light-emitting element 100C in FIGS. 11 to 13 is similar to the light-emitting element 100B in FIGS. 7 to 9. The difference between the two is that in the embodiment of FIGS. 11 to 13, the second electrode 160B and the through hole 140aB deviate from the geometric center Sc of the semiconductor structure S. In other words, a geometric center of the second electrode 160B, a geometric center of the through hole 140aB, and the geometric center Sc of the semiconductor structure S are not aligned. Referring to FIGS. 11 to 13, in this embodiment, the through hole 140aB biased to a certain side, the recess 120a biased to a certain side, and the second electrode 160B disposed in the through hole 140aB and the recess 120a can make the light field distribution of the light-emitting element 100C biased to a certain side, which is more suitable for application in specific fields (such as but not limited to: a display used in a car).

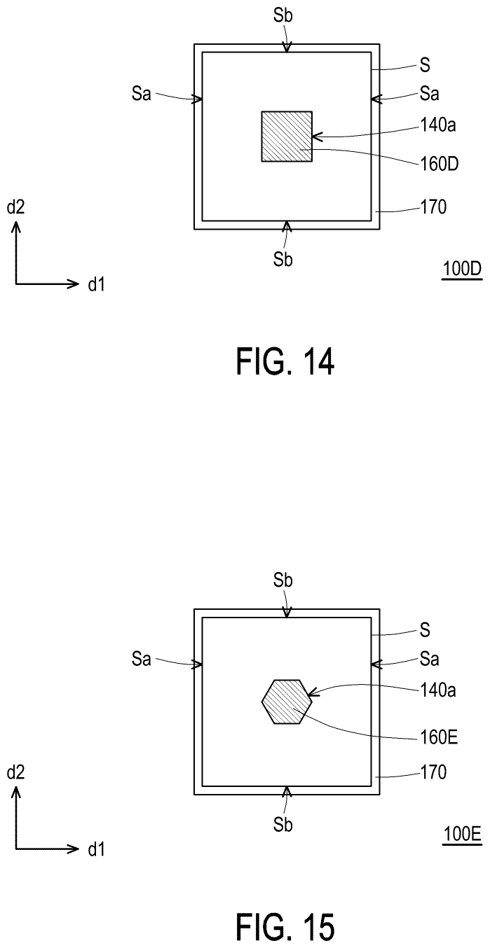

FIG. 14 is a top or bottom view of a light-emitting element according to an embodiment of this disclosure. The light-emitting element 100D of FIG. 14 is similar to the light-emitting element 100 of FIG. 2. The difference between the two is that the shapes of the second electrodes 160 and 160D are different. In the embodiment of FIG. 2, the shape of the second electrode 160 may be circular. In the embodiment of FIG. 14, the shape of second electrode 160D may be square.

FIG. 15 is a top or bottom view of the light-emitting element of another embodiment of the present disclosure. The light-emitting element 100E of FIG. 15 is similar to the light-emitting element 100 of FIG. 2. The difference between the two is that the shapes of the second electrodes 160 and 160E are different. In the embodiment of FIG. 2, the shape of the second electrode 160 may be circular. In the embodiment of FIG. 15, the shape of second electrode 160E may be hexagonal.

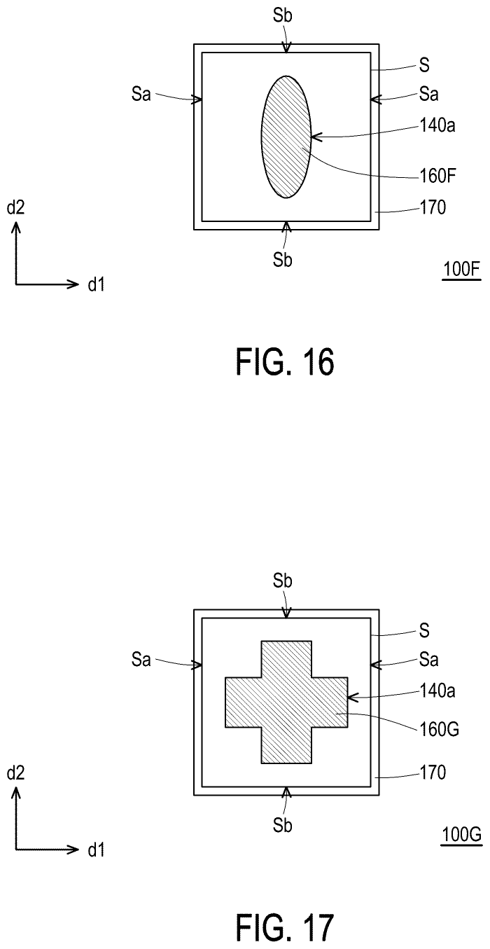

FIG. 16 is a top or bottom view of the light-emitting element of another embodiment of the disclosure. The light-emitting element 100F of FIG. 16 is similar to the light-emitting element 100 of FIG. 2. The difference between the two is that the shapes of the second electrodes 160 and 160F are different. In the embodiment of FIG. 2, the shape of the second electrode 160 may be circular. In the embodiment of FIG. 16, the shape of second electrode 160F may be oval.

FIG. 17 is a schematic top or bottom view of the light-emitting element of yet another embodiment of the disclosure. The light-emitting element 100G of FIG. 17 is similar to the light-emitting element 100 of FIG. 2. The difference between the two is that the shapes of the second electrodes 160 and 160G are different. In the embodiment of FIG. 2, the shape of the second electrode 160 may be circular. In the embodiment of FIG. 17, the shape of second electrode 160G may be cross-shaped.

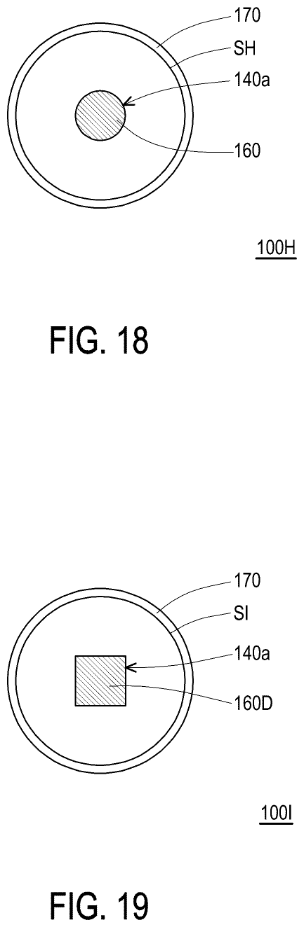

FIG. 18 is a top or bottom view of a light-emitting element according to an embodiment of the present disclosure. The light-emitting element 100H in FIG. 18 is similar to the light-emitting element 100 in FIG. 2. The difference between the two is that the shapes of their semiconductor structures S and SH are different. In the embodiment of FIG. 2, in the top view of the light-emitting element 100, the semiconductor structure S may be rectangular. In the embodiment of FIG. 18, in the top view or bottom view of the light-emitting element 100H, the semiconductor structure SH may be circular.

FIG. 19 is a top or bottom view of the light-emitting element of another embodiment of the present disclosure. The light-emitting element 100I of FIG. 19 is similar to the light-emitting element 100D of FIG. 14. The difference between the two is that the shapes of their semiconductor structures S and SI are different. In the embodiment of FIG. 14, in the top view or bottom view of the light-emitting element 100D, the semiconductor structure S may be rectangular. In the embodiment of FIG. 19, in the top view or bottom view of the light-emitting element 100I, the semiconductor structure SI may be circular.

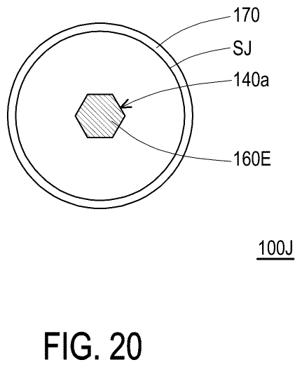

FIG. 20 is a top or bottom view of the light-emitting element of another embodiment of the disclosure. The light-emitting element 100J in FIG. 20 is similar to the light-emitting element 100E in FIG. 15. The difference between the two is that the shapes of their semiconductor structures S and SJ are different. In the embodiment of FIG. 15, in the top view or bottom view of the light-emitting element 100E, the semiconductor structure S may be rectangular. In the embodiment of FIG. 20, in the top view or bottom view of the light-emitting element 100J, the semiconductor structure SJ may be circular.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A light-emitting element comprising:
a first type semiconductor layer;
a second type semiconductor layer, disposed opposite to the first type semiconductor layer;
an active layer, disposed between the first type semiconductor layer and the second type semiconductor layer;
an intrinsic semiconductor layer having microstructures, wherein the second type semiconductor layer is disposed between the intrinsic semiconductor layer and the active layer;
a first electrode and a second electrode respectively disposed on opposite sides of the active layer and electrically connected to the first type semiconductor layer and the second type semiconductor layer respectively;
wherein the intrinsic semiconductor layer has a through hole, the second type semiconductor layer has a recess, the through hole of the intrinsic semiconductor layer is connected with the recess of the second type semiconductor layer, and the second electrode is disposed in the through hole of the intrinsic semiconductor layer and the recess of the second type semiconductor layer.

2. The light-emitting element according to claim 1, wherein the second electrode has a first portion and a second portion connected to the first portion, the first portion of the second electrode is disposed in the through hole of the intrinsic semiconductor layer and the recess of the second type semiconductor layer, the second portion of the second electrode is located outside the through hole of the intrinsic semiconductor layer and the recess of the second type semiconductor layer and is disposed on the microstructures of the intrinsic semiconductor layer, and the first electrode is translucent.

3. The light-emitting element according to claim 1, wherein a first direction and a second direction are intersect with each other and are substantially parallel to the active layer, the through hole of the intrinsic semiconductor layer has a first length and a second length respectively in the first direction and the second direction, and the first length is less than the second length.

4. The light-emitting element according to claim 3, wherein a semiconductor structure comprises the first type semiconductor layer, the second type semiconductor layer and the active layer, the semiconductor structure has first side walls arranged in the first direction and second side walls arranged in the second direction, the light-emitting element further comprises:
a reflective structure, disposed on the second side walls and not disposed on the first side walls.

5. The light-emitting element according to claim 3, wherein a semiconductor structure comprises the first type semiconductor layer, the second type semiconductor layer and the active layer, and the through hole of the intrinsic semiconductor layer is offset from a geometric center of the semiconductor structure.

6. The light-emitting element according to claim 1, wherein a material of the second electrode is metal.

7. The light-emitting element according to claim 1, wherein the second electrode is conical.

8. The light-emitting element according to claim 1, wherein the intrinsic semiconductor layer has a thickness, the thickness is T, a sum of a depth of the recess and a depth of the through hole is D, and D falls in a range of (T+0.2 μm) to (T+1.5 μm).

9. The light-emitting element according to claim 1, wherein a side wall of the intrinsic semiconductor layer that defines the through hole is substantially consistent with a side wall of the second type semiconductor layer that defines the recess.

10. The light-emitting element according to claim 1, wherein in a top view of the light-emitting element, the through hole of the intrinsic semiconductor layer substantially overlaps with the recess of the second type semiconductor layer.
